(19) United States
(12) Patent Application Publication
(10) Pub. No.: US 2007/0290955 A1
(43) Pub. Date: Dec. 20, 2007

(54) ORGANIC ELECTROLUMINESCENT DISPLAY DEVICE AND MANUFACTURING METHOD THEREOF

(75) Inventor: Hiroki TSUJIMURA, Kyoto (JP)

Correspondence Address: ROHM CO., LTD.;C/O KEATING & BENNETT, LLP, 8180 GREENSBORO DRIVE, SUITE 850, MCLEAN, VA, 22102, US

(73) Assignee: ROHM CO., LTD., Kyoto (JP)

(21) Appl. No.: 11/762,105

(22) Filed: Jun. 13, 2007

(30) Foreign Application Priority Data
Jun. 14, 2006 (JP) 2006-164526

(51) Int. Cl. G09G 3/30

(52) U.S. Cl. 345/76

(57) ABSTRACT

An organic EL display device having high fineness includes a plurality of pixels arrayed in series. Each of the pixels includes a first area, a second area, and a third area arrayed in series along the array direction of the pixels. The first area, the second area, and the third area define areas adapted to emit different colored light, i.e. red, green, and blue. The first area of each of the pixels, and the third area of the pixel adjoining each of the pixels define the areas adapted to emit light of the same colors, the third area being adjacent to the first area. The second areas of the pixels adjoining each other define the areas adapted to emit light of colors different from each other.

### BACKGROUND OF THE INVENTION

1. Field of the Invention

The present invention relates to an organic EL display device capable of displaying full-color images by emitting, e.g. red light, green light, and blue light, and a manufacturing method of the organic EL display device.

2. Description of Related Art

A conventional organic EL display device includes a number of pixels for emitting, e.g. red light, green light, and blue light, to display an intended image in full color. The organic EL display device is provided with a number of pixels arranged in a matrix pattern. Concerning pixels arranged in series in a certain direction, three areas for respectively emitting red light, green light, and blue light are arranged in series in the same order on each of the pixels.

FIGS. 6 through 8 are diagrams showing a method for manufacturing the organic EL display device. FIGS. 6 through 8 show a process for forming pixels 91 each having a first area 91a, a second area 91b, and a third area 91c on a transparent substrate 92. First, as shown in FIG. 6, a mask 95 is disposed opposite to the transparent substrate 92 formed with a number of anode electrodes 93. A hole injection layer and a hole transport layer (both of which are not shown) for constituting an organic layer are formed on the anode electrodes 93. The mask 95 is made of, e.g., a metal, and is constructed such that plural strip-like shielding portions 95a are spaced away from each other by a gap 95b. The shielding portion 95a has a width that is substantially equal to the sum of the widths of two of the first area 91a, the second area 91b, and the third area 91c. The gap 95b has a width substantially equal to the width of one of the first area 91a, the second area 91b, and the third area 91c. Red light-emitting layers 94R are formed by, e.g., vapor deposition on exposed portions of the transparent substrate 92 through the gaps 95b in the mask 95. Then, the mask 95 is shifted to the position shown in FIG. 7. Then, green light-emitting layers 94G are formed on exposed portions of the transparent substrate 92 through the gaps 95b. Subsequently, blue light-emitting layers 94B are formed in a state that the mask 95 is shifted to the position shown in FIG. 8. By performing the above-described steps, the red light-emitting layers 94R, the green light-emitting layers 94G, and the blue light-emitting layers 94B are repeatedly formed on the transparent substrate 92 in the same order. Thereafter, an electron transport layer, an electron injection layer, cathode layers, and the like (all of which are not shown) for constituting the organic layer are formed. Thus, the organic EL display device capable of displaying images in full color is manufactured.

There is a strong demand for manufacturing the organic EL display device with high accuracy and fineness. It is required to reduce the size of the pixels to obtain high fineness. Reducing the pixel size requires reducing the widths of the red light-emitting layers 94R, the green light-emitting layers 94G, and the blue light-emitting layers 94B. Reducing the widths of the red light-emitting layers 94R, the green light-emitting layers 94G, and the blue light-emitting layers 94B requires reducing the width of the shielding portions 95a of the mask 95. A tension force is applied to the shielding portions 95a in the longitudinal direction thereof to avoid unwanted contact of the shielding portions 95a with the transparent substrate 92 in disposing the mask 95 as opposed to the transparent substrate 92. As the width of the shielding portions 95a is decreased, the shielding portions 95a is likely to be broken due to the tension force applied thereto. Also, the shielding portions 95a may sag because of heat applied thereto during the vapor deposition. These drawbacks make it very difficult to obtain high fineness in the conventional organic EL display device.

### SUMMARY OF THE INVENTION

In order to overcome the problems in the prior art, preferred embodiments of the present invention provide an organic EL display device that has high accuracy and fineness, and a manufacturing method thereof.

An organic EL display device according to a first preferred embodiment of the present invention includes a plurality of pixels arrayed in series. Each of the pixels includes a first area, a second area, and a third area arrayed in series along the pixel array direction. The first area, the second area, and the third area define an area arranged to emit light of a first color, an area arranged to emit light of a second color, and an area arranged to emit light of a third color, respectively, the first color, the second color, and the third color being different from each other. The first area of each of the pixels, and the third area of the pixel adjoining each pixel define the areas arranged to emit light of the same color, the third area being adjacent to the first area. Second areas of the pixels adjoining each other define an area arranged to emit light of colors that are different from each other.

In the above-described unique arrangement, the areas arranged to emit light of the same color on the first through the third areas are formed in a state that two adjoining areas and one area are alternately arranged every other group of three areas of the first through the third areas. Accordingly, in the case where the areas arranged to emit light of the same color are formed on the first through the third areas, it is possible to use a mask having shielding portions each having a width that is substantially equal to the sum of the widths of the three areas including the first through the third areas. Use of the mask is advantageous in minimizing and preventing breakage of or damage to the shielding portions.

A method for manufacturing an organic EL display device according to a second preferred embodiment of the present invention is a method for manufacturing an organic EL display device provided with a plurality of pixels arrayed in series, each of the pixels including a first area, a second area, and a third area arrayed in series along the pixel array direction, and the first area, the second area, and the third area serving as an area arranged to emit light of a first color, an area arranged to emit light of a second color, and an area arranged to emit light of a third color, respectively, the first color, the second color, and the third color being different from each other. The method includes, with the use of a mask having a plurality of shielding portions each having a width for covering the three areas, the shielding portions being spaced away from each other by a first gap and a second gap alternately provided between the shielding portions, the first gap having a width adapted to expose two of the three areas and the second gap having a width adapted to expose one of the three areas, a step of forming a plurality of areas for emitting light of the first color at exposed portions on a substrate through the gaps in a state in which the mask is opposed to the substrate, a step of forming one of a plurality of areas for emitting light of the second color and a plurality of areas for emitting light of the third color in a state in which the mask is positioned such that one of two sets of areas having two adjoining areas for emitting light of the first color is exposed through the gap having the width for exposing the one area; and a step of forming the other of the plurality of areas for emitting light of the second color and the plurality of areas for emitting light of the third color in a state in which the mask is positioned such that the other of the sets of areas having the two adjoining areas for emitting light of the first color is exposed through the gap having the width for exposing the one area.

In the above-described arrangement, the mask is provided with the shielding portions, each having the width substantially equal to the sum of the widths of three areas including the first through the third areas. As the width of the shielding portion is increased, the shielding portion is less likely to be broken due to a tension force applied thereto or sagging thereof. This is advantageous in minimizing the likelihood that the manufacturing may be suspended in the manufacturing step using the mask due to the broken or sagging shielding portions. Also, assuming that the shielding portion of the mask, as used in the conventional arrangement, whose width is substantially equal to the sum of the widths of two of the first through the third areas, and the shielding portion of the mask to be used in preferred embodiments of the present invention have substantially the same widths, it is possible to reduce the size of the pixel to about two-thirds, as compared with the conventional arrangement. Accordingly, the arrangements of preferred embodiments of the present invention are advantageous in providing the organic EL display device with high fineness.

These and other elements, steps, characteristics, features and advantages of the present invention will become more apparent from the following detailed description of preferred embodiments with reference to the accompanying drawings.

### BRIEF DESCRIPTION OF THE DRAWINGS

FIG. 1 is a partial cross-sectional view of an organic EL display device according to a preferred embodiment of the present invention.

FIG. 2 is a partially enlarged cross-sectional view of the organic EL display device according to a preferred embodiment of the present invention.

FIG. 3 is a partial cross-sectional view showing a step of forming red light-emitting layers in a method for manufacturing the organic EL display device shown in FIG. 1.

FIG. 4 is a partial cross-sectional view showing a step of forming green light-emitting layers in the method for manufacturing the organic EL display device shown in FIG. 1.

FIG. 5 is a partial cross-sectional view showing a step of forming blue light-emitting layers in the method for manufacturing the organic EL display device shown in FIG. 1.

FIG. 6 is a partial cross-sectional view showing a step of forming red light-emitting layers in a method for manufacturing a conventional organic EL display device.

FIG. 7 is a partial cross-sectional view showing a step of forming green light-emitting layers in the method for manufacturing the conventional organic EL display device.

FIG. 8 is a partial cross-sectional view showing a step of forming blue light-emitting layers in the method for manufacturing the conventional organic EL display device.

### DETAILED DESCRIPTION OF THE PREFERRED EMBODIMENTS

In the following, preferred embodiments of the present invention are described referring to the drawings.

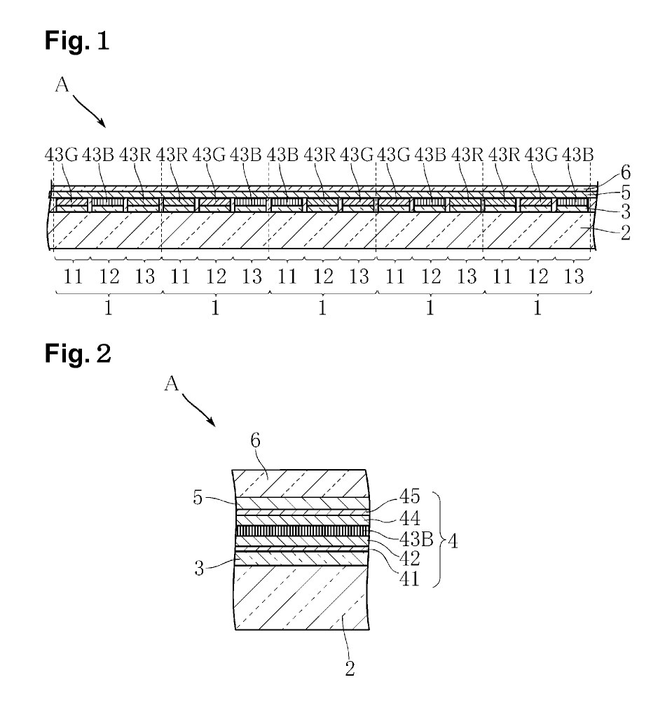

FIGS. 1 and 2 are diagrams showing an example of an organic EL display device according to a preferred embodiment of the present invention. The organic EL display device A of the present preferred embodiment includes a transparent substrate 2, anode electrodes 3, an organic layer 4, and cathode electrodes 5. The organic EL display device A is adapted to display images in full color by controlling light emission of multitudes of pixels 1, each having a first area 11, a second area 12, and a third area 13. As shown in FIG. 1, the pixels 1 are arranged in a matrix pattern, wherein arrays of the pixels 1 are arranged in series in a first direction, and arrays of the pixels 1 are arranged in a direction that is substantially perpendicular to the first direction. In FIG. 1, elements other than red light-emitting layers 43R, green light-emitting layers 43G, and blue light-emitting layers 43B of the organic layer 4 are not shown.

The transparent substrate 2 is preferably made of, e.g., a glass material, and supports the anode electrodes 3, the red light-emitting layers 43R, the green light-emitting layers 43G, the blue light-emitting layers 43B, and the cathode electrodes 5 thereon. A lower portion of the transparent substrate 2 in FIG. 1 serves as a display area of the organic EL display device A. Specifically, the organic EL display device A is preferably a bottom emission type electroluminescent device that outputs light through the transparent substrate 2.

The anode electrodes 3 are adapted to apply an electric field to the organic layer 4 for hole injection, and are electrically conductive with a positive polarity of an unillustrated power source. The anode electrode 3 is a transparent electrode preferably made of, e.g. ITO, and is preferably formed into a strip shape.

The cathode electrodes 5 are adapted to apply an electric field to the organic layer 4 for electron injection, and are electrically conductive with a negative polarity of the power source. The cathode electrode 5 is preferably a layer made of, e.g., aluminum, with a relatively large reflectance, and is preferably formed into a strip shape.

In the present preferred embodiment, the anode electrodes 3 and the cathode electrodes 5 extend substantially perpendicular to each other, with the organic layer 4 being interposed at the intersections thereof. With this arrangement, the organic EL display device A is controlled by a passive matrix method.

The organic layer 4 has a laminated structure, wherein a hole injection layer 41 made of an organic compound, a hole transport layer 42, the light emitting layers 43R, 43G, 43B, an electron transport layer 44, and an electron injection layer 45 are formed one over the other. The hole injection layer 41 increases hole injection efficiency with respect to the organic layer 4. The hole transport layer 42 efficiently transports holes to the light emitting layers 43R, 43G, and 43B, and a function of increasing recombination efficiency of recombining electrons with holes in the light emitting layers 43R, 43G, and 43B. Examples of a material for forming the hole injection layer 41 may include, e.g. copper phthalocyanine, metal-free phthalocyanine, and aromatic amines (TPAC, 2Me-TPD, α-NPD, etc.). Examples of a material for forming the hole transport layer 42 may include, e.g., 1,1-bis(4-di-p-aminophenyl)cyclohexane, galvasol, derivatives thereof, triphenylamine, and derivatives thereof.

The light emitting layers 43R, 43G, and 43B are layers adapted to emit red light, green light, and blue light, respectively. The light emitting layers 43R, 43G, and 43B contain a light emitting material, and define a field for generating excitons by recombination of holes from the anode electrodes 3 with electrons from the cathode electrodes 7. The excitons cause the light emitting material to emit light while moving in the light emitting layers 43R, 43G, and 43B. By selecting a proper kind of the light emitting material to be contained in the light emitting layers 43R, 43G, and 43B, the light emitting layers 43R, 43G, and 43B are allowed to emit red light, green light, and blue light, respectively. Examples of the light emitting material may include fluorescent or phosphorus light emitting materials e.g. tris(8-quinolinolato) aluminum complex, bis(benzoquinolinolato)beryllium complex, ditolylvinyl biphenyl, tri(dibenzoylmethyl)phenanthroline europium complex (Eu(DBM)3(Phen)), and phenylpyridine iridium compound. Polymeric light emitting materials such as poly(p-phenylenevynylene), polyalkylthiophene, polyfluorene, and derivatives thereof may also be usable.

The electron transport layer 44 and the electron injection layer 45 are arranged so as to cover the light emitting layers 43R, 43G, and 43B. The electron injection layer 45 increases electron injection efficiency with respect to the organic layer 4. The electron transport layer 44 efficiently transports electrons in the light emitting layers 43R, 43G, and 43B, and increases recombination efficiency of recombining electrons with holes in the light emitting layers 43R, 43G, and 43B. Examples of a material for forming the electron transport layer 44 and the electron injection layer 45 may include, e.g., anthraquinodimethane, diphenylquinone, perylene tetracarboxylic acid, triasol, oxasol, oxadiasol, benzoxasol, and derivatives thereof.

In this preferred embodiment, the light emitting layers adapted to emit light of the same colors among the light emitting layers 43R, 43G, and 43B are formed on the first area 11 and the third area 13 adjoining each other of the adjoining pixels 1. The light emitting layers 43R and 43R (43G and 43G; 43B and 43B) formed on the adjoining first areas 11 and third areas 13 are repeatedly arranged in the order of red, blue, and green from leftward direction to rightward direction in FIG. 1. Also, one of the light emitting layers 43R, 43G, and 43R, whose color is different from those of the other two of the light emitting layers 43R, 43G, and 43B formed on the first area 11 and the third area 13 of each pixel 1, is formed on the second area 12 of the each pixel 1. By forming the light emitting layers 43R, 43G, and 43B in the aforementioned manner, each of the pixels 1 is allowed to have one set of the light emitting layers 43R, 43G, and 43B.

The anode electrodes 3, the organic layer 4, and the cathode electrodes 5 are covered by a protective layer 6. The protective layer 8 is formed into a transparent insulating film made of, e.g., SiO₂ or other suitable material.

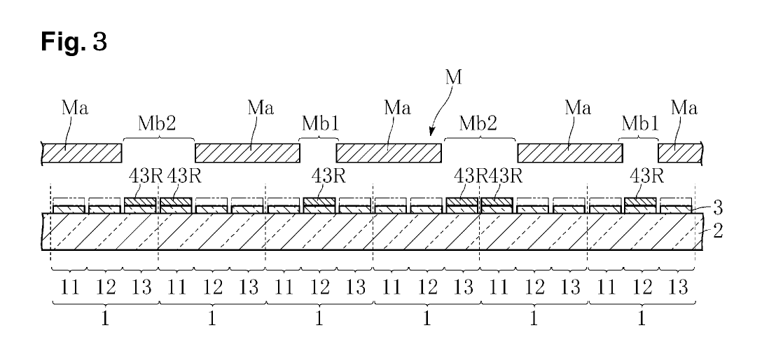

In the following, an example of a method for manufacturing the organic EL display device A is described referring to FIGS. 3 through 5.

First, a mask M as shown in FIG. 3 is prepared. The mask M is preferably made of, e.g., a metal, and is formed with a number of shielding portions Ma. The shielding portion Ma is a strip member extending in a depthwise direction on the plane of FIG. 3, and has a width that is substantially equal to the sum of the widths of three areas constituted of the first through the third areas 11, 12, and 13. The shielding portions Ma are spaced away from each other by a gap Mb1 or a gap Mb2. The gap Mb1 has a width that is substantially equal to the width of any one of the areas 11, 12, and 13. The gap Mb2 has a width that is substantially equal to the sum of the widths of any two of the three areas 11, 12, and 13. The gap Mb1 and the gap Mb2 are alternately formed. As shown in FIG. 3, the anode electrodes 3 are formed on the transparent substrate 2 in advance. Although not illustrated in FIG. 3, the hole injection layer 41 and the hole transport layer 42 shown in FIG. 2 are formed. Then, the mask M is disposed opposite to the transparent substrate 2 in such a state that the second areas 12 are exposed through the gaps Mb1 and that the first areas 11 and the third areas 13 adjoining each other of the adjoining pixels 1 are exposed through the gaps Mb2. In this state, the red light-emitting layers 43R are formed at the exposed portions of the first through the third areas 11, 12, and 13 through the gaps Mb1 and Mb2 preferably by, e.g., vapor deposition. The red light-emitting layers 43R formed by this step are arranged in such a manner that the two red light-emitting layers 43R covering the adjoining first and third areas 11 and 13, and the one red light-emitting layer 43R covering the second area 12 are alternately arranged at every other group of three areas of the first through the third areas 11, 12, and 13.

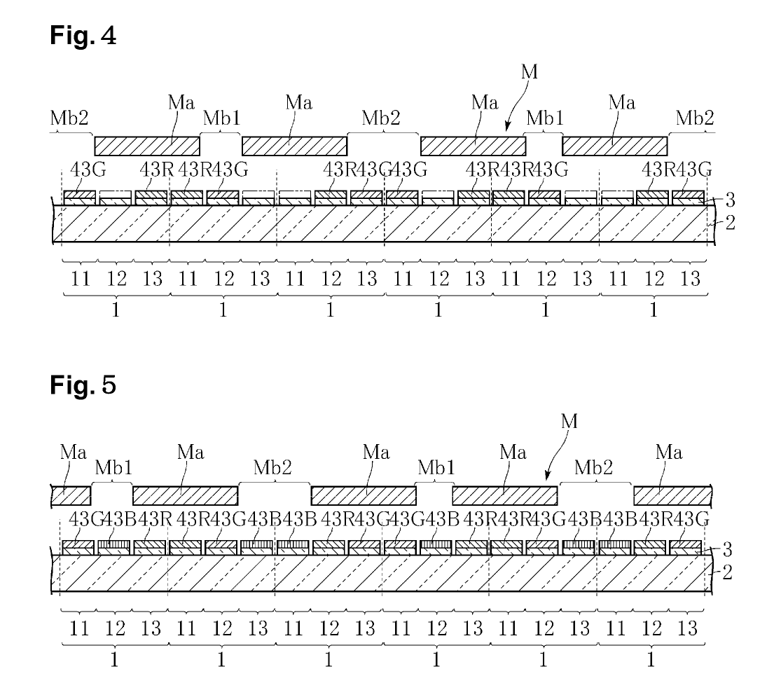

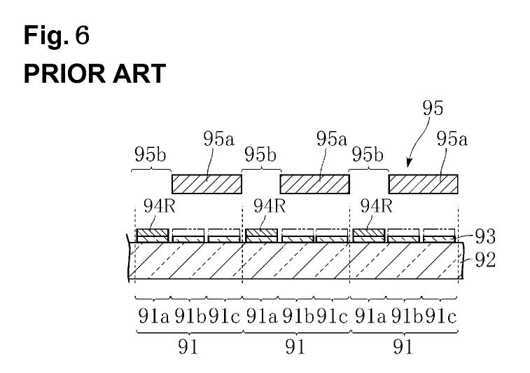

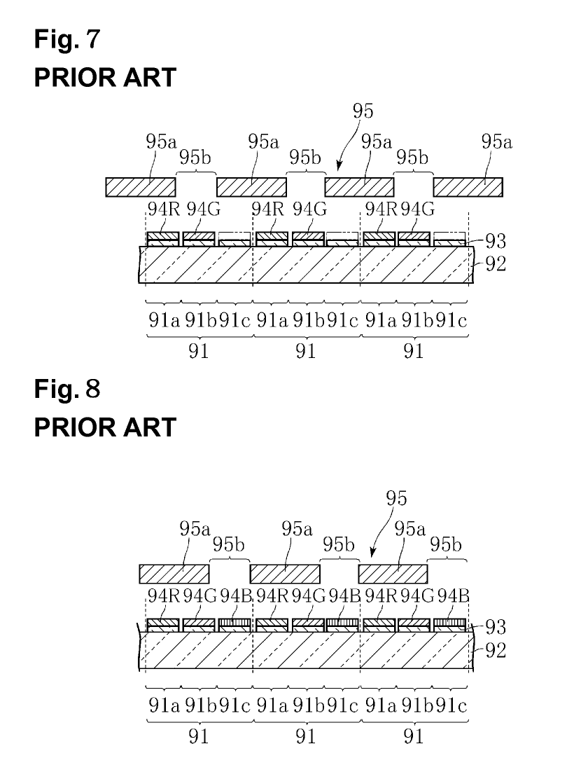

Next, the mask M is shifted along the transparent substrate 2 as shown in FIG. 4. Specifically, the mask M is shifted to a position in which the second area 12 which is located on the right of the two adjoining red light-emitting layers 43R is exposed through the gap Mb1. In other words, the shifting is conducted to shift the mask M to a position such that the third area 13 and the first area 11, which are located on the right of the one red light-emitting layer 43R, other than the two adjoining red light-emitting layers 43R, are exposed through the gap Mb2. In this state, the green light-emitting layers 43G are formed at the exposed portions of the first through the third areas 11, 12, and 13 through the gaps Mb1 and Mb2.

Then, the mask M is shifted again along the transparent substrate 2 as shown in FIG. 5. In this step, the mask M is shifted to a position in which the second area 12 which is located on the left of the two adjoining red light-emitting layers 43R is exposed through the gap Mb1. In other words, the shifting is conducted to shift the mask M to a position such that the first area 11 and the third area 13, which are located on the left of the one red light-emitting layer 43R, other than the two adjoining red light-emitting layers 43R, are exposed through the gap Mb2. By the shifting, all the first through the third areas 11, 12, and 13 including the areas on which the light emitting layers 43R and 43G have not been formed in the preceding steps are exposed through the gaps Mb1 and Mb2. Then, in this state, the blue red-light emitting layers 43B are formed. By performing the abovementioned steps, the two adjoining red light-emitting layers 43R, the two adjoining green light-emitting layers 43G, and the two adjoining blue light-emitting layers 43B are formed on the corresponding sets of the adjoining first and third areas 11 and 13 in the order of red, blue, and green from leftward direction to rightward direction in FIG. 5. Also, one of the light emitting layers 43R, 43G, and 43B, whose color is different from those of the other two of the light emitting layers 43R, 43G, and 43B formed on the first area 11 and the third area 13 of each pixel 1, is formed on the second area 12 of the each pixel 1. As a result, the light emitting layers 43R, 43G, and 43B for emitting light of the colors different from each other are formed on the first through the third areas 11, 12, and 13 of each of the pixels 1.

After the light emitting layers 43R, 43G, and 43B are formed, the electron transport layer 44, the electron injection layer 45, the cathode electrodes 5, and the protective layer 6 are successively formed in this order by a well-known technique, whereby the organic EL display device A shown in FIG. 1 is manufactured.

Next, an operation of the organic EL display device A is described.

In this preferred embodiment, the mask M for producing the light emitting layers 43R, 43G, and 43B is provided with the shielding portions Ma, each having the width that is substantially equal to the sum of the widths of the three areas of the first through the third areas 11, 12, and 13. Accordingly, as compared with the conventional arrangement, in which the shielding portion has the width that is substantially equal to the sum of the widths of two of the three areas 11, 12, and 13, the shielding portion Ma in the present preferred embodiment is much less likely to be broken or damaged by a tension force or other force. For instance, assuming that the width of the shielding portion in the conventional arrangement and the width of the shielding portion Ma in the present preferred embodiment are substantially the same, the organic EL display device A in the present preferred embodiment is advantageous in reducing the size of the pixel 1 to about two-thirds of the pixel size in the conventional arrangement. Accordingly, the present preferred embodiment is advantageous in providing the organic EL display device A with high fineness.

Further, arranging the light emitting layers 43R, 43G, and 43B in the aforementioned manner facilitates use of the mask M for forming the light emitting layers 43R, 43G, and 43B commonly for the colors. As a result, there is no need to prepare dedicated or specific masks for individual colors, which maximizes processing and work efficiency and reduces manufacturing cost and time.

The organic EL display device and the manufacturing method thereof according to the present invention are not limited to the foregoing preferred embodiments. Specific arrangements on the components of the organic EL display device and the manufacturing method thereof according to preferred embodiments of the present invention may be modified or altered in various ways within the scope of the present invention.

The arrangement of the light emitting layers 43R, 43G, and 43B in above-described preferred embodiments is merely an example of the color arrangements concerning first, second, and third colors possible in the present invention. Any colors of red, green, and blue may be assigned to the first through the third colors defined in preferred embodiments of the present invention. The order of colors from leftward direction to rightward direction in the cross-sectional view of FIG. 1 may differ depending on the color assignment. The example of the color arrangement as defined in preferred embodiments of the present invention is advantageous in attaining the high fineness. Also, the two light emitting layers 43R and 43R, (43G and 43G; 43B and 43B) to be formed on the adjoining first area 11 and third area 13 are described as light emitting layers independent of each other, for convenience of explanation. Alternatively, a single light emitting layer having a size substantially equal to the size of two joined light emitting layers 43R and 43R (43G and 43G; 43B and 43B) may be formed.

In the preferred embodiments described above, the color separation on the areas 11, 12, and 13 is performed by the light emitting layers 43R, 43G, and 43B. The present invention is not limited to this. An element for determining the color of light to be emitted from the areas 11, 12, and 13 can be formed by a technique analogous to the technique described in the preferred embodiments of the present invention and the present invention is applicable to any arrangement other than the one described in the preferred embodiments of the present invention. Also, the first through the third colors for realizing full-color image display are not limited to red, green, and blue.

While preferred embodiments of the present invention have been described above, it is to be understood that variations and modifications will be apparent to those skilled in the art without departing the scope and spirit of the present invention. The scope of the present invention, therefore, is to be determined solely by the following claims.

What is claimed is:

1. An organic EL display device comprising:
a plurality of pixels arrayed in series, each of the plurality of pixels including a first area, a second area, and a third area arrayed in series along a pixel array direction, the first area, the second area, and the third area respectively defining an area arranged to emit light of a first color, an area arranged to emit light of a second color, and an area arranged to emit light of a third color, the first color, the second color, and the third color being different from each other; wherein
the first area of each of the pixels and the third area of an adjoining pixel define areas arranged to emit light of the same color, the third area being adjacent the first area; and
second areas of the pixels adjoining each other define areas arranged to emit light of colors different from each other.

2. A method for manufacturing an organic EL display device provided with a plurality of pixels arrayed in series, each of the pixels including a first area, a second area, and a third area arrayed in series along a pixel array direction, the first area, the second area, and the third area respectively defining an area arranged to emit light of a first color, an area arranged to emit light of a second color, and an area arranged to emit light of a third color, the first color, the second color, and the third color being different from each other, the method comprising the steps of:
providing a mask having a plurality of shielding portions each having a width for covering the three areas, the shielding portions being spaced away from each other by a first gap and a second gap alternately formed between the shielding portions, the first gap having a width for exposing two of the three areas, and the second gap having a width for exposing one of the three areas;
forming, with the mask placed over a substrate, a plurality of areas for emitting light of the first color on portions of the substrate exposed through the gaps;
forming either a plurality of areas for emitting light of the second color or a plurality of areas for emitting light of the third color with the mask set to a position such that one of two sets of areas sandwiching two adjoining areas for emitting light of the first color is exposed through the gap having the width for exposing one area; and
forming the other of the plurality of areas for emitting light of the second color and the plurality of areas for emitting light of the third color with the mask set to a position such that the other of the sets of areas sandwiching the two adjoining areas for emitting light of the first color is exposed through the gap having the width for exposing the one area.
